(19) United States
(12) Patent Application Publication
(10) Pub. No.: US 2025/0264807 A1
(43) Pub. Date: Aug. 21, 2025

(54) PRODUCTION CONTROL METHOD FOR A PROJECTION EXPOSURE APPARATUS, PROJECTION EXPOSURE APPARATUS, AND PROJECTION EXPOSURE METHOD

(71) Applicant: Carl Zeiss SMT GmbH, Oberkochen (DE)

(72) Inventor: Martin LEUERMANN, Schwaebisch Gmuend (DE)

(21) Appl. No.: 19/201,017

(22) Filed: May 7, 2025

Related U.S. Application Data
(63) Continuation of application No. PCT/EP2023/080032, filed on Oct. 27, 2023.

(30) Foreign Application Priority Data
Nov. 7, 2022 (DE) 10 2022 211 735.2

(51) Int. Cl. G03F 7/00

(52) U.S. Cl. CPC G03F 7/70266; G03F 7/70225

(57) ABSTRACT

A production control method controls the operation of a microlithographic projection exposure apparatus comprising a projection lens; a wavefront manipulation system comprising a manipulator and an optical encoder, the wavefront manipulation system configured to controllably influence the wavefront of the projection radiation, and a controller configured to control the manipulator of the manipulation system by generating an actuator travel command which defines a change in the spatial pose along an actuator travel of the optical element. The controller in at least one error-optimized mode of operation selectively establishes actuator travels of the manipulator with consideration being given to cyclical errors of the phase-based optical encoder of the wavefront manipulation system, in such a way that a second cyclical error at the end of an actuator travel substantially corresponds to a first cyclical error at the start of an actuator travel.

### CROSS REFERENCE TO RELATED APPLICATIONS

This is a Continuation of International Application PCT/EP2023/080032, which has an international filing date of Oct. 27, 2023, and the disclosure of which is incorporated in its entirety into the present Continuation by reference. This Continuation also claims foreign priority under 35 U.S.C. § 119(a)-(d) to and also incorporates by reference, in its entirety, German Patent Application DE 10 2022 211 735.2 filed on Nov. 7, 2022.

### FIELD

The techniques disclosed herein relate to a production control method for controlling the operation of a microlithographic projection exposure apparatus for exposing a radiation-sensitive substrate to at least one image of a pattern, and to a projection exposure apparatus configured to perform the production control method, and to a projection exposure method performable therewith.

### BACKGROUND

Microlithographic projection exposure methods are predominantly used nowadays for producing semiconductor components and other finely structured components, for example microlithographic masks (reticles). Here, use is made of masks (photomasks, reticles) or other pattern creating devices, which carry or provide a specific pattern of a structure to be imaged, for example a line pattern of a layer of a semiconductor component. In a projection exposure apparatus, the pattern is positioned in the beam path between an illumination system and a projection lens so that the pattern is located in the region of the object plane of the projection lens. A substrate to be exposed, for example a semiconductor wafer coated with a radiation-sensitive layer (resist, photoresist), is held so that a radiation-sensitive surface of the substrate is arranged in the region of an image plane of the projection lens optically conjugate to the object plane. In an exposure procedure, the pattern is illuminated with the aid of the illumination system which forms, from the radiation of a primary radiation source, illumination radiation that is directed at the pattern and incident on the pattern within an illumination field having a defined shape and size. During an exposure procedure the radiation modified by the pattern travels through the projection lens as projection radiation, said projection lens imaging the pattern onto the substrate to be exposed.

A projection exposure with wavefront aberrations that are as small as possible under all imaging conditions is required to guarantee imaging of the mask structures on the substrate that is as precise as possible.

To this end, projection exposure apparatuses of the type considered here are equipped with a wavefront manipulation system for controllably influencing, while the projection exposure apparatus is in operation, the wavefront of the projection radiation directed at the substrate through the projection lens. A wavefront manipulation system is designed to change the imaging properties of the system in a defined fashion during the operation of the projection exposure apparatus and on the basis of control signals from a control unit. A wavefront manipulation system comprises at least one manipulable optical element which interacts with the projection radiation when used as intended and serves to influence the wavefront. The manipulable optical element is assigned a manipulator for reversibly changing the spatial pose of the manipulable optical element or at least of a portion of the manipulable optical element. A manipulator may comprise one or more actuators or actuating elements. Further, the manipulable optical element is assigned a measuring system for measuring changes in pose of the manipulable optical element or of the portion capable of being changed in terms of its pose. This enables a controlled operation of the manipulator adjustments.

Typically, a wavefront manipulation system in an operationally ready configuration comprises a multiplicity of manipulable optical elements. Projection lenses are frequently equipped with manipulators, which render it possible to correct wavefront errors by changing the state of individual manipulable optical elements (e.g., lens elements and/or mirrors) of the projection lens. An example of such a change in state is a change of pose in one or more of the six rigid-body degrees of freedom of the relevant manipulable optical element. The wavefront effective at the substrate may also be changed by a manipulation or displacement of the mask and/or substrate.

In the systems considered here, the measuring systems for measuring the changes in pose are based on an optical distance measurement at a suitable measurement wavelength. Such a measuring system comprises at least one phase-based optical encoder for measuring changes in the pose of the manipulable optical element or of a portion thereof by evaluating phase information from a measurement signal captured at a measurement wavelength. Such measuring systems operate contactlessly and can achieve high measurement accuracies.

The control device, or controller, for controlling a manipulator generates actuator travel commands which define a change in the spatial pose along an actuator travel of the assigned manipulable element, to be carried out by the manipulator.

In the currently known correction methods for projection lithography, the correction with wavefront feedback is implemented on the basis of a wavefront measurement. In the process, the wavefront is measured, for example in the region of the image plane, and correction scenarios are established from the measurement results, in order to reduce or entirely avoid possible wavefront errors by way of manipulations of manipulable elements. To this end, the manipulators are displaced over corresponding actuator travels.

It was recognized that the correction options have certain limitations in the case of such systems.

### SUMMARY

Against this background, the techniques disclosed herein are based on the problem of improving and expanding the options for wavefront correction in generic projection exposure apparatuses and methods, inter alia in relation to the accuracy of the manipulator settings.

Example embodiments of the techniques disclosed herein may address this problem by via a production control method as described herein. A projection exposure apparatus and a projection exposure method having the features of claim 11 are also provided. The wording of all the claims is incorporated by reference in the content of the description.

In accordance with one formulation of the disclosed techniques, a production control method of the type set forth at the outset is characterized in that the control apparatus, in at least one error-optimized mode of operation, selectively establishes actuator travels of the at least one manipulator with consideration being given to cyclical errors of the phase-based optical encoder, in such a way that a second cyclical error at the end of an actuator travel substantially corresponds to a first cyclical error at the start of an actuator travel.

The techniques disclosed herein are based inter alia on the following insights of the inventors. In many typical correction scenarios, the spatial pose of individual optical elements is changed by actuator travels up to the order of one or a few micrometers (μm) and/or by angles up to the order of microradians (μrad). In this case, pose errors (errors in the spatial pose) of the optical elements may create aberration errors in what is known as the line-of-sight contribution to the wavefront, which are of the same order as the pose errors themselves.

This means that a pose error of one picometer (pm) can create a line-of-sight aberration of approximately one pm. However, the set wavefront errors must be set with picometer accuracy. In the case of travels (actuator travels) of the order of μm or μrad, the individual degrees of freedom should thus be able to be approximated accurately over 6 orders of magnitude in order to avoid inadvertently set aberrations of more than approximately one picometer. This places huge demands on the measuring system, which determines the spatial pose, which is to say the position and orientation, of the individual mirrors or lens elements and thereby sets the travels thereof.

A corresponding statement applies to manipulations in which it is not the complete optical element that is changed in terms of its pose (in at least one rigid-body degree of freedom) but only one or more portions of same, relative to other portions that are unchangeable in terms of their pose. This may be the case, in particular, for deformable optical elements, for example if the optical element is bent at one or more points in the edge region, for example at two opposing points, under the action of a force applied by an actuating element and a locally restricted deformation which does not encompass the entire optical element is created as a result.

The measuring systems considered here are based on an optical distance measurement. Such a measuring system comprises at least one phase-based optical encoder for measuring changes in the pose of the manipulable optical element by evaluating phase information from a measurement signal captured at a measurement wavelength.

A phase-based optical encoder within the meaning of this application converts phase information from a diffraction spectrum or interference spectrum into distance information. For example, a phase-based optical encoder can be electromechanical equipment which uses a light source, light detectors, and an optical grating to convert the angle position or movement into an electrical signal. In some optical encoders, a light source radiates light at or through a grating which is marked such that the light passes through or is blocked. The optical detectors register the passage of light and create a corresponding electrical impulse. Suitably designed interferometer arrangements can also be used as phase-based optical encoders. In this case, the distance information emerges from the establishment of optical path length differences from interferograms.

It was recognized that, on account of the periodicity of the phase information, such measuring systems suffer from pronounced cyclical errors which for a measurement wavelength of λₘₑₛₛ occur at distances of λ_{zyk}=n·λₘₑₛₛ or

$${λ}_{zyk} = \frac{{λ}_{mess}}{n} ,$$

where n∈ [symbol] . These cyclical errors can be modeled as sinusoidal oscillations and can have an amplitude of many picometers. To avoid inadvertent aberrations above ˜pm, use should only be made of travels x<<λ_{zyk} as a consequence.

With the aid of the disclosed techniques, it is possible to avoid the disadvantages, arising from the underlying principles, of phase-based optical encoders without losing their advantages (e.g., in respect of measurement accuracy). Specifically, it is possible to use travels substantially longer than λ_{zyk} for all degrees of freedom/encoders and, in the process, keep the cyclical errors significantly below their amplitude, with neither the phase nor the amplitude of the cyclical errors being known for the individual encoders.

The scope of this application considers wavefront manipulation systems which comprise at least one manipulable optical element which interacts with the projection radiation when used as intended and serves to influence the wavefront, wherein the manipulable optical element is assigned a manipulator for reversibly changing the spatial pose of the manipulable optical element or at least of a portion thereof. The manipulable optical elements typically include lens elements and/or mirrors of the projection lens. The wavefront effective at the substrate may also be changed by a manipulation (e.g., displacement and/or deformation) of the mask and/or substrate. As application-specific components, these are not constituent parts of a projection exposure apparatus but are held by corresponding controllable holding devices of the projection exposure apparatus (reticle stage, wafer stage) during operation and may thus be included as manipulable elements of a wavefront manipulation system. In this application, these are referred to as manipulable “optical” elements because they interact with the radiation to be influenced. The term “spatial pose” in this case describes the combination of position and orientation of an optical element or of one of its portions and therefore is tantamount to the term “relative position”. To improve readability, this application also uses the term “pose” in the sense of a spatial pose or the relative position.

In principle, the solution is based on the selection of suitable target domains in the space of encoder values. In this case, the known periodicity λ_{zyk} of the cyclical errors is to be exploited and regions in the parameter space where the cyclical errors at the end point of an actuator travel substantially have the same phase as at the starting point are to be identified. In other words, the cyclical error at the end of an actuator travel should adopt substantially the same value as at the start of the actuator travel. To this end, the sought-after and hence permissible target encoder values must be located in the vicinity of integer multiples of the periodicity λ_{zyk} of the cyclical errors.

The terms “domain” and “target domain” each describe a relatively small region around those encoder values where the phase of the cyclical error at the end of an actuator travel exactly corresponds to the corresponding phase at the start of the actuator travel. Small deviations from exactly the same phase are therefore permissible. A target domain preferably encompasses a region in which the absolute value of the cyclical error deviates by no more than 10% of the maximum value of the cyclical error from the value at exactly the same phase. This is also expressed by the phrase “substantially corresponds to”. The deviation may also be smaller, for example no more than 5% or no more than 2%. The absolute phase, which is to say the absolute value of the cyclical errors, may remain unknown both before and after the displacement of the manipulator, which is to say after the traversal of the actuator travel. However, it needs to be ensured that the cyclical error before and after the displacement or after the change in pose is at least substantially identical, so that the actually set actuator travel (difference between the pose before and after the correction) is not influenced by cyclical errors.

A cyclical error is an error which is caused by the measurement principle and which influences the functional relationship between a set manipulated variable, in this case a specific actuator travel of a manipulator, and the output signal of the measuring system (i.e., the encoder output or the encoder value) respectively belonging to this manipulated variable.

In the case of an ideal (error-free), linearly operating measuring system, this relationship would for example be described by a straight line with a specific gradient, with the result that the manipulated variable and the associated output signal of the measuring system are related to one another in the same way for each value of the manipulated variable. By contrast, if a measuring system with a cyclical error is present, this relationship is no longer exactly true. Instead, the functional relationship only holds approximately, with there being periodic deviations from the exact functional relationship.

If, in accordance with the proposal of the disclosed techniques, only those manipulated variable values which lead to the phase of the cyclical error at the start of an actuator travel and at the end of the actuator travel being substantially the same are admitted, then the influence of the cyclical error is eliminated since all locations with the same phase of the output signal afflicted by the cyclical error are described by a smooth function which has the same profile as the ideal function not afflicted by the cyclical error and which may have only a small offset vis-à-vis the ideal function.

If consideration is given to the restriction of the permissible actuator travels to certain values, as proposed by the disclosed techniques, then it is also possible that the control apparatus permits actuator travel commands for actuator travels that are long in comparison with the size of the cyclical error, in particular at least ten times as long or at least 100 times as long. For example, the control device may permit actuator travel commands for actuator travels of 1 μm or more or 1 μrad or more.

By using the disclosed techniques, manipulations that were not previously reliably possible are now possible with few errors during the operation of a projection exposure apparatus. According to a development, provision is made for the wavefront manipulation system to be operated such that, within exposure time intervals, the manipulator is controlled on the basis of actuator travel commands generated in the error-optimized mode of operation. In particular, within exposure time intervals, the manipulator can be controlled exclusively on the basis of actuator travel commands generated in the error-optimized mode of operation. The following explanations are provided to give an understanding of the significance of this option.

As mentioned at the outset, a wavefront manipulation system generally comprises a wavefront control loop with a wavefront measuring device for measuring the wavefront of the projection radiation and for generating wavefront measurement signals, wherein the wavefront measuring device is signal-connected to the control unit and the control unit generates actuator travel commands for the manipulators on the basis of the wavefront measurement signals. The goal of such a control loop lies in the permanent minimization or restriction of wavefront errors to an acceptable level. Such a wavefront control loop is also provided for in preferred embodiments of projection exposure apparatuses.

With such a correction with wavefront feedback, precise control of the travels or actuator travels are rendered unnecessary since there is a wavefront measurement after a new set point (i.e., a combination of positions or spatial poses for all movable or manipulable optical elements) is approximated. This wavefront measurement is subsequently used as an input of an optimization in a further iteration step. Thus, the optimization is implemented iteratively here, wherein the travels still required after a few iteration steps are small enough to be able to neglect cyclical errors.

Now, consideration should be given to the fact that such a wavefront measuring device does not generate measurement signals during exposure time intervals of a projection exposure method. Exposure time intervals are those time intervals during which the projection radiation is incident on the substrate to be exposed, and exposed substrates are produced thereby. The wavefront measurement can only be performed outside of exposure time intervals in exposure breaks.

By using the disclosed techniques, it is now possible to precisely control manipulators even within exposure time intervals, specifically on the basis of actuator travel commands generated in the error-optimized mode of operation. Thus, blind operation is now possible, which is to say operation during which manipulator adjustments are not performed on the basis of wavefront measurement values but expected aberrations during the exposure are derived from a model. Hence, the manipulable optical elements can even be moved during the exposure of individual wafers or individual wafer portions (dies). By all means, travels of the order of micrometers or microradians may be necessary in this context. Such blind operation is now possible under the supervision of the phase-based optical encoders since the measurements of the travels are no longer limited by the cyclical errors.

There are various options for carrying out manipulator adjustments using the disclosed techniques, with the precision of said adjustments practically not being impaired by cyclical errors of the utilized phase-based optical encoders.

A one-stage variant provides for a complete actuator travel to be established with consideration being given to the cyclical errors and for the manipulator to be adjusted accordingly. The length of the actuator travel can be one or more orders of magnitude longer than the cyclical error.

According to a development, actuator travel commands are established in a multi-stage optimization operation. In this case, in order to establish an actuator travel command, a first actuator travel is established in a first stage proceeding from a start position of an actuator movement with a first cyclical error, with consideration being given to specifiable boundary conditions but no consideration being given to cyclical errors. Then, in a second stage, a second actuator travel is established proceeding from an end point of the first actuator travel, with consideration being given to cyclical errors, by virtue of a second cyclical error which is closest to the cyclical error at the end point being established, said second cyclical error substantially corresponding to the first cyclical error at the start of the first actuator travel. Following this second step, the value for the established actuator travel is located in the region of a target domain, within which the cyclical error is already sufficiently small.

A further improvement can be obtained within this target domain, by virtue of a post-optimization of the actuator travel for establishing an end position of the actuator travel being implemented in a third stage that follows the second stage, wherein the end position is located within a tolerance range about the end point of the second actuator travel.

### BRIEF DESCRIPTION OF THE DRAWINGS

Further advantages and aspects of the disclosed techniques are evident from the claims and from the description of exemplary embodiments of the disclosed techniques, which will be explained below with reference to the figures.

FIG. 1 shows components of an EUV microlithographic projection exposure apparatus according to an exemplary embodiment;

FIG. 2 shows a schematic diagram for explaining cyclical errors in phase-based measuring systems;

FIG. 3 shows fictitious cyclical errors in two encoders A (left) and B (right), on the basis of travels in encoders A and B;

FIG. 4 shows combined cyclical errors of encoders A and B, wherein the square sum of both errors is depicted on the left and the maximum value of both errors is depicted on the right;

FIG. 5 shows a restriction in the allowed travels in encoder values (dark circle) in order to reduce the contribution of cyclical errors;

FIG. 6 shows an example of the selection of suitable target domains (dark circles) of the same phase or same cyclical encoder errors, and an example of a two-stage optimization for determining an optimum within the valid domains.

### DETAILED DESCRIPTION

Exemplary embodiments of the disclosed techniques are described below on the basis of the operation of a projection exposure apparatus for EUV lithography. However, the applicability is not restricted thereto. The disclosed techniques can also be used in projection exposure apparatuses that operate with radiation from other wavelength ranges, for example from the deep ultraviolet radiation (DUV) range, for example at approx. 193 nm wavelength.

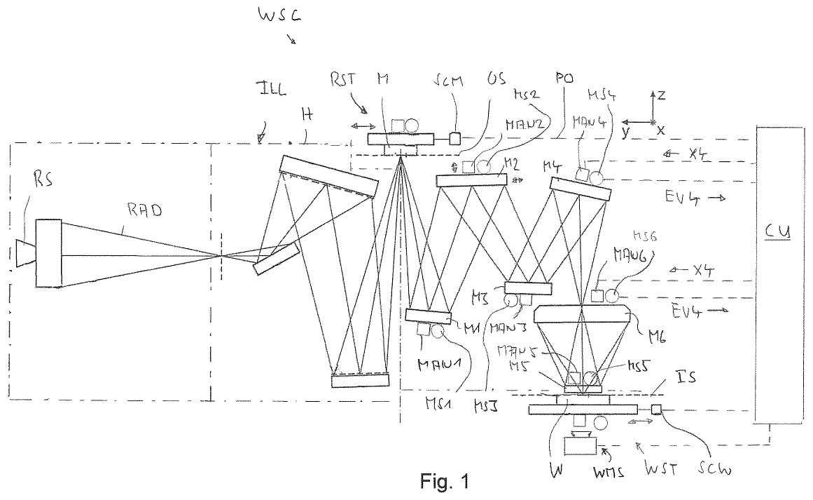

Schematic FIG. 1 shows components of an EUV microlithographic projection exposure apparatus WSC for exposing a radiation-sensitive substrate W arranged in the region of an image plane IS of a projection lens PO to at least one image of a pattern of a reflective mask M arranged in the region of an object plane OS of the projection lens.

The projection exposure apparatus is operated with the radiation from a primary radiation source RS. An illumination system ILL serves to receive the radiation from the primary radiation source and shape illumination radiation directed at the pattern of the mask M. The projection lens PO serves to image the structure of the pattern on the light-sensitive substrate W.

The primary radiation source may be, inter alia, a laser plasma source or a gas discharge source or a synchrotron-based radiation source. Such radiation sources generate a radiation RAD in the extreme ultraviolet range (EUV range), in particular at wavelengths between 5 nm and 15 nm. In order that the illumination system and the projection lens can operate in this wavelength range, they are constructed with optical elements which are reflective to EUV radiation.

The radiation RAD emanating from the radiation source RS is collected by a collector and guided into the illumination system ILL. The illumination system shapes the radiation and thereby illuminates an illumination field situated in the object plane OS of the projection lens PO or in the vicinity thereof. In this case, the shape and size of the illumination field determine the shape and size of the effectively used object field OF in the object plane OS. As a rule, the illumination field is slot-like with a large aspect ratio between width and height.

During the operation of the apparatus, a reflective mask M is arranged in the object plane OS. The projection lens PO images the pattern of the mask with a reduced scale in the image plane in which the substrate to be exposed, for example a semiconductor wafer, is arranged.

A device RST for holding and manipulating the mask M (reticle) is arranged such that the pattern arranged on the mask is located in the object plane OS, also referred to as reticle plane here, of the projection lens PO. With the aid of a scan drive SCM, the mask is movable in this plane for scanner operation in a scanning direction (y-direction) perpendicularly to the reference axis of the projection lens (parallel to the z-direction).

The substrate W to be exposed is held by a device WST comprising a scanner drive SCW in order to move the substrate synchronously with the mask M perpendicularly to the reference axis in a scanning direction (y-direction). Depending on the design of the projection lens PO, these movements of mask and substrate can be carried out parallel or antiparallel to one another.

The device WST, which is also referred to as “wafer stage”, and the device RST, which is also referred to as “reticle stage”, are constituent parts of a scanner device which is controlled by way of a scan control device which, in the embodiment, is integrated in the central control device CU of the projection exposure apparatus.

The projection lens in this example comprises six mirrors M1 to M6 with concavely or convexly curved mirror surfaces. These may be free-form surfaces. An intermediate image is generated between object field and image field. For example, examples of projection lenses are specified in the laid-open application DE 10 2021 201 162 A1, the disclosure of which in this respect is incorporated by reference in the content of this description. Other structures, for example with more or fewer mirrors with or without an intermediate image, are possible.

All optical components of the projection exposure apparatus WSC are housed in an evacuable housing H. The projection exposure apparatus is operated in vacuo.

For example, EUV projection exposure apparatuses are known from the laid-open application DE 10 2021 201 162 A1, the disclosure of which is incorporated by reference in the content of this description.

The projection exposure apparatus comprises a wavefront measuring system WMS, which is configured to carry out a measurement of the wavefront of the projection radiation travelling in the projection lens from the mask to the substrate to be exposed. A spatially resolving measurement for a plurality of field points is preferably provided. By way of example, wavefront measuring systems of the type described in U.S. Pat. Nos. 7,333,216 A1 or 6,650,399 A1 may be provided, the disclosure of the said patents in this respect being incorporated by reference in the content of this description.

The projection exposure apparatus WSC comprises a production control system configured to undertake a near-instantaneous fine optimization of imaging-relevant properties of the projection exposure apparatus in response to environmental influences and other disturbances and/or on the basis of stored control data. To this end, the production control system comprises a multiplicity of manipulators which permit a targeted intervention into the projection behavior of the projection exposure apparatus. An actively actuatable manipulator contains one or more actuating elements (or one or more actuators), the current manipulated value of which can be changed on the basis of control signals of the production control system by virtue of defined manipulated value changes being undertaken.

The projection lens or the projection exposure apparatus is equipped with, inter alia, a wavefront manipulation system, which is configured to controllably change the wavefront of the projection radiation travelling from the object plane OS to the image plane IS, in the sense that the optical effect of the wavefront manipulation system is able to be variably adjusted by way of control signals of the production control system.

The wavefront manipulation system comprises a manipulator MAN1 to MAN6 for each mirror of the projection lens. A manipulator contains one or more actuating elements or actuators, the current manipulated value of which can be changed or adjusted on the basis of control signals of the control system. The manipulators each enable a displacement of the assigned optical element in the x-direction and y-direction and hence substantially parallel to a plane which extends in the vicinity of the reflective mirror surfaces. Displacements parallel to the z-direction are also possible. Further changes in the spatial poses of the mirrors are possible as a result of a rotation about a tilt axis oriented parallel to the x-axis. As a result, the angle of the reflecting surface of the mirror can be changed in relation to the incident radiation. Expressed more generally, the manipulators considered here are configured to change the spatial pose of the respectively assigned optical element on the basis of actuator travel commands (reference signs X1 to X6) while carrying out a rigid-body movement along a specified actuator travel.

Other embodiments additionally or alternatively include at least one manipulator for the targeted deformation of a deformable optical element. Hence, an optically effective surface can be bent locally by virtue of specific portions of the optical element being changed relative to other portions in terms of the pose.

Here, an “actuator travel” is understood to mean a change in a state variable (the pose) of a manipulable optical element or portion of same, carried out by manipulator actuation, along the actuator travel for the purposes of changing the optical effect of said optical element. Such an actuator travel defined by a change of the spatial pose of the optical element or one of its portions is specified by way of target change variables of the associated manipulator. By way of example, the manipulation may be or comprise a displacement of the optical element in a specific direction. By way of example, the target change variable can define a path length to be covered or an angular range to be covered in the case of a displacement.

To enable a controlled operation of the manipulator adjustments, each manipulable optical element is assigned a measuring system MS1, MS2, etc., for measuring changes in the pose of the manipulable optical element (measuring systems MS1 to MS6). The measuring systems for measuring the changes in pose are based on an optical distance measurement at a measurement wavelength λₘₑₛₛ. Such a measuring system comprises at least one phase-based optical encoder for measuring changes in the pose of the manipulable optical element by evaluating phase information from a measurement signal captured at a measurement wavelength. The measured encoder values EV1, . . . , EV4, etc. are transmitted to the control device CU.

The control device CU is configured to carry out an actuator travel-generating optimization algorithm. The optimization algorithm serves to optimize a merit function, which is also referred to as figure-of-merit function.

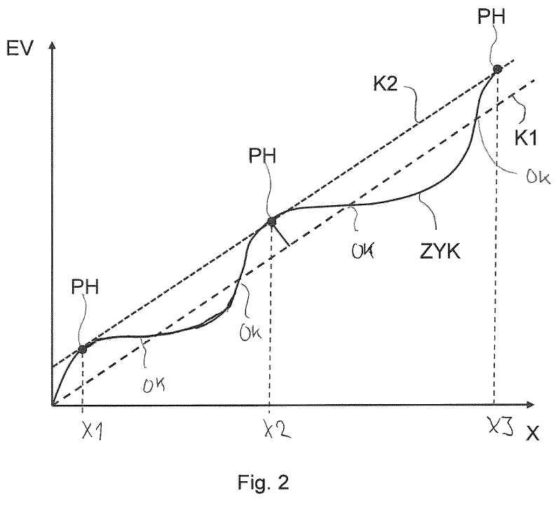

To elucidate the problem of the cyclical error, FIG. 2 shows a diagram indicating the functional relationship between the actuator travel X of a manipulator (x-axis) and the output signal EV of the corresponding encoder as the encoder value EV. To keep the illustration simple, consideration is given to a nominally linear encoder whose encoder value increases linearly with a linear increase in actuator travel. The ideal functional relationship (without error) is represented by the straight line K1. The curve ZYK illustrates the relationship between actuator travel X and encoder value EV in the case of a phase-based optical encoder afflicted by a cyclical error. Accordingly, it is only the encoder values at the actuator travels OK that correspond to the “correct” actuator travels, and these are separated by periodically varying deviations with a maximum error at the phases PH. In these regions, the encoder would output an encoder value suggesting an actuator travel that does not correspond to the true actuator travel.

Consider a case in which the manipulator is at actuator travel X1 at the start of a change in actuator travel. This location precisely corresponds to a maximum of the cyclical error (point PH). If (in an error-optimized mode of operation) only those end points of an actuator movement where the cyclical error has the same phase again (points PH) are permitted, then the corresponding encoder values EV are located on a straight line K2 which has exactly the same slope as the ideal straight line K1. Accordingly, the traveled actuator travel can be deduced exactly (without errors) from the encoder values EV.

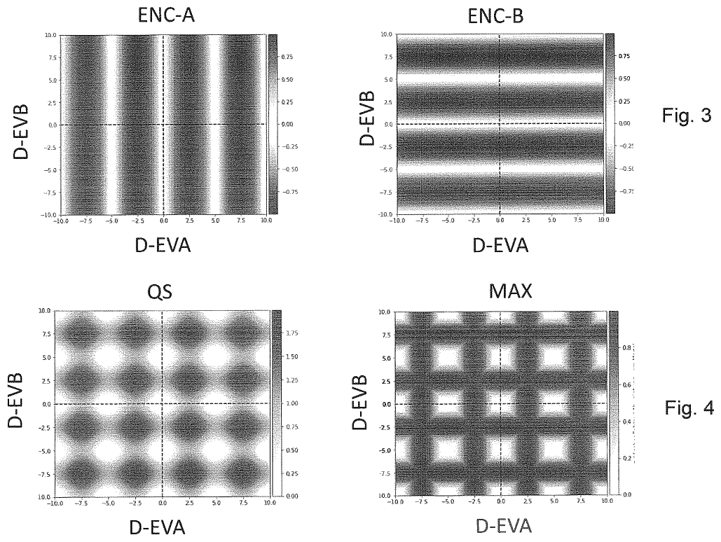

FIG. 3 shows the cyclical error for a fictitious measuring system consisting of two encoders, ENC-A (left) and ENC-B (right). The abscissa plots the changes D-EVA in the encoder value A and the ordinate plots the changes D-EVB in the encoder value B. White regions show encoder values where the cyclical error is close to zero; the maximum values of the deviations are located in the darkest regions.

Depending on the application, the maximum value of the cyclical error of both encoders, the quadratic sum of the cyclical errors, or any other metric may be relevant during the positioning, which is to say the adjustment of the spatial pose. To visualize the critical variables for the combination of encoders ENC-A and ENC-B, FIG. 4 depicts the quadratic sum QS on the left and the maximum value MAX on the right.

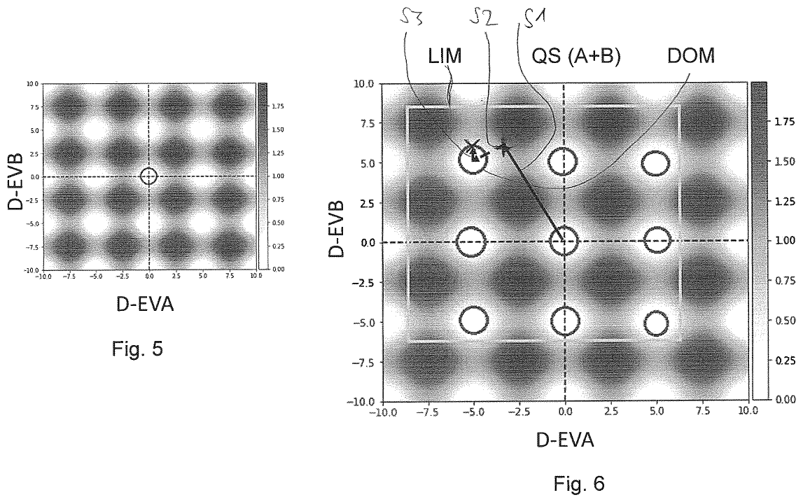

FIG. 5 is used to illustrate a typical procedure when handling errors of a measuring system. In essence, this solution consists in restricting the corresponding manipulator ranges, which is to say the actuator travel ranges of the manipulator. In other words: to correct the aberration, the degrees of freedom are only conceded a travel interval in which the errors of the measuring system, in this case the cyclical errors, do not exceed an acceptable threshold.

A restriction δx<<λ_{zyk} for the travels δx typically arises as a result. FIG. 5 depicts an example of such a restriction of the allowed travels in encoder variables. In this case, the circle in the center encloses that region of relatively small errors within which the permissible actuator travels are allowed to be located.

To further understand the implications of the solution proposed by the inventors, consideration should be given to the following:

Without loss of generality, the phase of the cyclical errors is assumed to be zero here. In general, the encoders may be at any desired encoder value before the manipulators are displaced, which is to say before the changes in manipulated value. Thus, the cyclical error may already assume any value at the starting point of the movement. In other words, the grayscale value map in the background of FIG. 5 could also be displaced such that the circle of tolerable actuator travels is located on a maximum of the encoder errors, which is to say in a dark region, or anywhere between a dark and a white region.

Naïvely in such a case one might therefore also think that the restriction to the dark circle only allows regions with particularly high cyclical errors for the optimization.

In practice, the extent of the cyclical error at the starting point of an actuator movement is irrelevant: Since the intention is only to precisely displace optical surfaces and the absolute positions thereof need not be determined, the cyclical error may assume any arbitrary value provided that its contribution before and after the displacement of the optical element is approximately the same. In other words and with reference to the grayscale representation, only regions with approximately the same brightness are allowed to be enclosed in the circle of tolerance. Which brightness, which is to say which absolute error, is enclosed by the allowed regions is irrelevant to the travels.

In essence, the solutions proposed here are based on a selection of suitable target domains in the space of encoder values. The object here is to exploit the known periodicity λ_{zyk} of the cyclical errors (on account of the measurement wavelength) and to identify regions in the parameter space where the cyclical errors (substantially) have the same phase as at the initial point of an actuator movement, which is to say where the cyclical errors assume the same value.

To this end, the target encoder values must be located in the vicinity of integer multiples of the periodicity λ_{zyk} of the cyclical errors.

The absolute phase, which is to say the absolute value of the cyclical errors, remains unknown here, both before and after the displacement of the optical elements. However, it is ensured that the cyclical error before and after the displacement of the elements is substantially identical, and so the difference of the encoder values of the set actuator travel is not influenced by cyclical errors.

In FIG. 6, such a selection of suitable target domains DOM is represented by dark circles. In this case, the dark circles DOM enclose regions of the grayscale value map that have only approximately the same color, with the result that the distance or the difference between the initial point and any point within the domains should not be influenced, or only be influenced to a negligible extent, by cyclical errors. Additionally, the intervals for the encoders or travels can be restricted by further conditions, for example in order to reduce other (non-cyclical) errors. This is illustrated by the rectangle LIM in FIG. 6.

By way of the nine permissible target domains DOM, there now are far more parameter configurations of the encoder values available for correcting the aberrations than are made available by the “naïve restriction” from FIG. 5.

Consideration should be given to the fact that the effect appears unrealistically small in the simplified example shown since the number of admissible target domains is only increased from 1 to 9 target domains DOM of equal size. In practice, the use will be significantly greater, in particular because consideration usually should be given to a large number of encoders and travels. For illustrative purposes, consider a hypothetical system with 30 encoders and travels of ˜1 μm/μrad at λ_zyk˜100 nm. This yields an increase from 1 to

$$\sim {( \frac{1 µm}{100 nm} )}^{30} = {10}^{30}$$

allowed domains. In other words: The domains sample the entire parameter space very tightly and thus allow an optimum to be found, this optimum typically coming very close to the optimum of an unrestricted optimization (only the rectangular frame LIM as a restriction in FIG. 6).

An important advantage of this method moreover is the fact that cyclical errors with a periodicity of m·λ_{zyk} or

$$\frac{{λ}_{zyk}}{m}$$

m∈ [symbol] are also avoided. These cyclical errors with an integer fraction or multiple of the periodicity are further common errors of such position measuring systems.

An exemplary embodiment with a multi-stage optimization is explained below on the basis of arrows S1, S2, and S3 in FIG. 6, in order to introduce the principle of discrete domains. One option of obtaining a solution within the domains of valid encoder values when optimizing a travel consists of carrying out a multi-stage optimization with different boundary conditions.

In a first optimization step (arrow S1), it is for example possible to carry out an optimization without giving consideration to the cyclical measuring system errors. Such an optimization would perform the aberration reduction in accordance with a “conventional” wavefront metric and would optionally give consideration to boundary conditions (such as the limits of the rectangular box LIM in FIG. 6) in the process. These boundary conditions could give consideration to both rigid boundary conditions (e.g., QuadProg optimization) and weak boundary conditions (which are known as “elastic bands”). An optimum found thus would have been determined without consideration having been given to the cyclical errors and could for example mean a travel from the origin to the encoder values in FIG. 6 marked by a cross. The cyclical error would be relatively large there, since this end point is located at the edge of a particularly dark zone.

In a second step (arrow S2), the determined encoder values could be used to determine the closest domain DOM of valid encoder values. In other words, the calculated encoder values are set to the next integer multiple of the encoder period λ_{zyk}. The set of encoder values determined thus firstly has the same absolute cyclical error as the point of origin (and hence no relative, cyclical error as a result of the travel) and secondly is close to the previously determined optimum. In FIG. 6, this is the domain DOM of the nine domains situated top left.

In a third step (arrow S3), the variation of the travels is now restricted to within the found domain DOM. That is to say, only variations of the encoder values about x<<λ_{zyk} around the found, integer multiple of λ_{zyk} are still allowed at this point. For example, in FIG. 6, the dark cross could thus be found as the optimum of the encoder values. Here, too, it is possible to use both hard boundary conditions (QuadProg) and weak boundary conditions (“elastic bands”) for the optimization.

The found values represent the final result of the optimization and are therefore the encoder values which should be approximated in order to correct the wavefront aberrations.

It should be observed that the optimization within the found domain (step S3) is important in the context of real optimization problems and should by no means be construed as merely fine tuning of the found metric. Although there is little displacement of the travels here, the line-of-sight variables which are disturbed in the case of very small movements from the optimum can thus be corrected again or be “zeroed” within the domain. For real adjustment problems with regard to optical surfaces, such a final optimization is generally very advantageous.

There is also the option of a mixed integer optimization. The allowed domains for each encoder can be numbered by integers, for example so that, for eleven valid domains in each encoder value, the domains may be referred to as D_{{k}_{ᵢ}_{}} with kᵢ=−5, −4, . . . , 0, . . . , 4, 5 for each encoder i=1, . . . ,30 (5 in the positive direction and 5 in the negative direction for each encoder).

The optimization problem could now be defined as a mixed integer problem, where the indices kᵢ for all encoders i themselves represent integer parameters of the optimization while the travels xᵢ represent continuous values, relative to the center of the domain determined by the indices kᵢ.

This allows the optimization using standard optimization methods of mixed integer optimization. Like in the example explained above, the question regarding the global optimum must also be posed here, to the extent that these methods do not guarantee to have found the global optimum. The expected run time of such an optimization is typically significantly longer than in the case of the aforementioned multi-stage optimization.

Some aspects of the disclosed techniques and their exemplary embodiments can also be described as follows. This disclosed techniques relate to a method of avoiding measuring system-induced incorrect positioning of optical elements by suitably selecting allowed domains of measurement values. Cyclical errors in the measuring system are avoided by selecting domains with similar, expected cyclical errors (domains of “the same phase”). Domains are selected in the vicinity of integer multiples of the expected periodicity of cyclical errors λ_{zykl}. A multi-stage optimization for determining the best-possible domain in view of the given target function of the optimization and the given periodicity of the cyclical errors in the measuring system is possible.

What is claimed is:

1. A method comprising:
controlling operation of a projection exposure apparatus configured to expose a radiation-sensitive substrate to at least one image of a pattern, the projection exposure apparatus comprising:
a projection lens configured to image a part of the pattern arranged in a region of an object plane of the projection lens into an image plane of the projection lens; and
a wavefront manipulation system configured to controllably influence, while the projection exposure apparatus is in operation, a wavefront of projection radiation directed at the radiation-sensitive substrate through the projection lens, wherein the wavefront manipulation system comprises:
a manipulable optical element which interacts with the projection radiation when used as intended and serves to influence the wavefront, wherein the manipulable optical element is assigned a manipulator configured to reversibly change a spatial pose of the manipulable optical element or a spatial pose of a portion of the manipulable optical element, and wherein the manipulable optical element is assigned a measuring system having a phase-based optical encoder configured to measure changes in the spatial pose of the manipulable optical element or in the spatial pose of the portion of the manipulable optical element by evaluating phase information from a measurement signal; and
a controller configured to control the manipulator by generating an actuator travel command which defines a change in the spatial pose of the manipulable optical element along an actuator travel of the assigned manipulable optical element or in the spatial pose of the portion of the manipulable optical element along an actuator travel of the portion of the manipulable optical element, to be carried out by the manipulator, wherein the controlling the operation of the projection exposure apparatus comprises:
the controller, in an error-optimized mode of operation, selectively establishing an actuator travel of the manipulator with consideration being given to cyclical errors of the phase-based optical encoder, in such a way that a second cyclical error at an end of an actuator travel substantially corresponds to a first cyclical error at a start of an actuator travel.

2. The method of claim 1, wherein the establishing the actuator travel of the manipulator comprises establishing actuator travel commands configured to implement actuator travels which are large in comparison with a size of the first cyclical error or the second cyclical error and/or establishing actuator travel commands configured to implement actuator travels which are one micrometer (μm) or more or one microradian (μrad) or more.

3. The method of claim 1, wherein the wavefront manipulation system comprises a wavefront control loop with a wavefront measuring device configured to measure the wavefront of the projection radiation and generate wavefront measurement signals, wherein the wavefront measuring device is signal-connected to the controller and the controller generates actuator travel commands for the manipulator based on the wavefront measurement signals.

4. The method of claim 1, wherein the wavefront manipulation system is operated such that, within exposure time intervals, the manipulator is controlled based on actuator travel commands generated in the error-optimized mode of operation.

5. The method of claim 4, wherein the establishing the actuator travel of the manipulator comprises establishing the actuator travel commands in a multi-stage optimization operation, in which, in order to establish an actuator travel command, a first actuator travel is established in a first stage proceeding from a start position of an actuator movement with a first cyclical error, with consideration being given to specifiable boundary conditions but no consideration being given to cyclical errors, and, in a second stage, a second actuator travel is established proceeding from an end point of the first actuator travel, with consideration being given to cyclical errors, by virtue of a second cyclical error which is closest to a cyclical error at the end point being established, said second cyclical error substantially corresponding to the first cyclical error at the start of the first actuator travel.

6. The method of claim 5, wherein the establishing the actuator travels of the manipulator further comprises a post-optimization of the actuator travel configured to establish an end position of the actuator travel that is implemented in a third stage that follows the second stage, wherein the end position is located within a target domain.

7. A apparatus comprising:
a projection lens configured to image a part of a pattern arranged in a region of an object plane of a projection lens into an image plane of the projection lens;
a wavefront manipulation system configured to controllably influence, while the apparatus is in operation, a wavefront of projection radiation directed at a radiation sensitive substrate through the projection lens, wherein the wavefront manipulation system comprises a manipulable optical element which interacts with the projection radiation when used as intended and serves to influence the wavefront, wherein the manipulable optical element is assigned a manipulator configured to reversibly change a spatial pose of the manipulable optical element or a spatial pose of a portion of the manipulable optical element, and wherein the manipulable optical element is assigned a measuring system having a phase-based optical encoder configured to measure changes in the spatial pose of the manipulable optical element or in the spatial pose of the portion of the manipulable optical element by evaluating phase information from a measurement signal; and
a controller configured to control the manipulator by generating an actuator travel command which defines a change in the spatial pose of the manipulable optical element along an actuator travel of the assigned manipulable optical element or in the spatial pose of the portion of the manipulable optical element along an actuator travel of the portion of the manipulable optical element, to be carried out by the manipulator, wherein the controller is configured, in an error-optimized mode of operation, to selectively establish actuator travels of the manipulator with consideration being given to cyclical errors of the phase-based optical encoder, in such a way that a second cyclical error at an end of an actuator travel substantially corresponds to a first cyclical error at a start of an actuator travel.

8. The apparatus of claim 7, wherein the controller is configured to permit actuator travel commands configured to implement actuator travels which are large in comparison with a size of the first cyclical error or the second cyclical error and/or which are one micrometer (μm) or more or one microradian (μrad) or more.

9. The apparatus of claim 7, wherein the wavefront manipulation system comprises a wavefront control loop with a wavefront measuring device configured to measure the wavefront of the projection radiation and generate wavefront measurement signals, wherein the wavefront measuring device is signal-connected to the controller and the controller generates actuator travel commands for the manipulator based on the wavefront measurement signals, wherein the wavefront manipulation system is configured such that the manipulator is controlled based on actuator travel commands generated in the error-optimized mode of operation.

10. The apparatus of claim 7, wherein the controller is configured to establish actuator travel commands in a multi-stage optimization operation, in which, in order to establish an actuator travel command, a first actuator travel is established in a first stage proceeding from a start position of an actuator movement with a first cyclical error, with consideration being given to specifiable boundary conditions but no consideration being given to cyclical errors, and, in a second stage, a second actuator travel is established proceeding from an end point of the first actuator travel, with consideration being given to cyclical errors, by virtue of a second cyclical error which is closest to the cyclical error at the end point being established, said second cyclical error substantially corresponding to the first cyclical error at the start of the first actuator travel.

11. The apparatus of claim 10, wherein the controller is configured to perform a post-optimization of the actuator travel configured to establish an end position of the actuator travel is implemented in a third stage that follows the second stage, wherein the end position is located within a target domain.

12. A method comprising:
holding a mask between an illumination system and a projection lens of a projection exposure apparatus in such a way that a pattern of the mask is arranged in a region of an object plane of the projection lens;
holding a radiation sensitive substrate in such a way that a radiation-sensitive surface of the substrate is arranged in a region of an image plane of the projection lens optically conjugate to the object plane;
illuminating an illumination region of the mask with an illumination radiation provided by the illumination system;
projecting a part of the pattern of the mask located in the illumination region onto an image field on the substrate with the projection lens, wherein all beams of the projection radiation contributing to image creation in the image field form a projection beam path, and
influencing a wavefront of the projection radiation, which runs from the object plane to the image plane, by controlling manipulators of a wavefront manipulation system, wherein the wavefront manipulation system comprises a manipulable optical element which interacts with the projection radiation when used as intended and serves to influence the wavefront, wherein the manipulable optical element is assigned a manipulator configured to reversibly change a spatial pose of the manipulable optical element or a spatial pose of a portion of the manipulable optical element and wherein the manipulable optical element is assigned a measuring system having a phase-based optical encoder configure to measure changes in the spatial pose of the manipulable optical element or in the spatial pose at least of a portion of the manipulable optical element by evaluating phase information from a measurement signal; and
generating, via a controller, an actuator travel command which serves to control the manipulator and which defines a change in a spatial pose along an actuator travel of the assigned manipulable optical element or change in a spatial pose of a portion of the manipulable optical element along an actuator travel of the portion of the manipulable optical element, to be carried out by the manipulator, wherein the generating comprise the controller, in an error-optimized mode of operation, selectively establishing actuator travels of the manipulator with consideration being given to cyclical errors of the phase-based optical encoder, in such a way that a second cyclical error at an end of an actuator travel substantially corresponds to a first cyclical error at a start of an actuator travel.
